(19) United States
(12) Patent Application Publication
(10) Pub. No.: US 2006/0015789 A1
(43) Pub. Date: Jan. 19, 2006

(54) Apparatus and method for encoding/decoding using Concatenated Zigzag code in mobile communication system

(75) Inventors: Dong-Joon Shin, Seoul (KR); Song-Nam Hong, Seoul (KR)

Correspondence Address: DILWORTH & BARRESE, LLP, 333 EARLE OVINGTON BLVD., UNIONDALE, NY, 11553, US

(73) Assignees: SAMSUNG ELECTRONICS CO., LTD, Suwon-si (KR); SEOUL NATIONAL UNIVERSITY INDUSTRY FOUNDATION, Seoul (KR)

(21) Appl. No.: 11/154,764

(22) Filed: Jun. 16, 2005

(30) Foreign Application Priority Data
Jun. 16, 2004 (KR) 2004-44732

(51) Int. Cl. H04K 1/10; G06F 11/00; G06F 11/30; G08C 25/00; H03M 13/00; H04L 1/00

(52) U.S. Cl. 714/746

(57) ABSTRACT

Disclosed is a method for channel coding in a mobile communication system, which includes dividing information bits of length N into M sub-information bits according to a preset value; interleaving the M sub-information bits through corresponding interleavers corresponding to the M sub-information bits, respectively; and coding the interleaved sub-information bits through corresponding component encoders corresponding to the interleaved sub-information bits.

### PRIORITY

This application claims priority to an application entitled “Apparatus and Method for Encoding/Decoding using Concatenated Zigzag Code in Mobile Communication System” filed in the Korean Intellectual Property Office on Jun. 16, 2004 and assigned Serial No. 2004-44732, the contents of which are hereby incorporated by reference.

### BACKGROUND OF THE INVENTION

1. Field of the Invention

The present invention relates to a channel coding technique capable of improving system efficiency in the next generation mobile communication system, and more particularly to a channel coding method capable of reducing encoding complexity and decoding delay by improving performance of a Concatenated Zigzag (CZZ) code in the next generation mobile communication system.

2. Description of the Related Art

Currently, cellular communication systems using an International Mobile Telecommunication (IMT)-2000 specification, have been commercialized for use. These systems are also known as Third Generation (3G) mobile communication systems. Development of 3G systems were begun in the late 1990's with the goal of creating a cellular system which could provide wireless multimedia services, global roaming services, high-speed data services and other such services.

Because of rapidly increasing demands by users for transmitting a greater amount of data at faster speeds, existing mobile communication systems, (e.g., 3G mobile communication systems) have been improved to transmit this data at higher speeds. In other words, 3G mobile communication systems have evolved into packet service communication systems. Packet service communication systems transmit burst packet data to a plurality of Mobile Stations (MSs), which are compatible with the packet service communication systems.

As a result, packet service communication systems have been developed for a high-speed packet service. For example, a High Speed Downlink Packet Access (HSDPA) scheme has been standardized by a 3^{rd} Generation Partnership Project (3GPP), which is the standards organization for a 3G asynchronous mobile communication system. 3 GPP has recently introduced an Adaptive Modulation and Coding (AMC) scheme, a Hybrid Automatic Retransmission Request (HARQ) scheme, a Fast Cell Select (FCS) scheme and other such schemes, in order to support high-speed packet data transmissions.

Hereinafter, the AMC scheme will be described from among the schemes for the high-speed packet service.

The AMC scheme is a data transmission scheme for improving total use efficiency of a cell by determining different channel modulation schemes and coding schemes according to channel conditions of the cell, i.e., between a Base Station (BS) and a MS. The AMC scheme includes a plurality of modulation schemes and a plurality of coding schemes. The AMC scheme combines the modulation schemes with the coding schemes, thereby modulating and coding channel signals.

Conventionally, combinations of modulation schemes and coding schemes are referred to as a Modulation and Coding Scheme (MCS), and it is possible to define a plurality of MCSs from level 1 to level N according to the number of the MCSs.

In other words, the AMC scheme adaptively determines the MCS level according to the wireless channel conditions between the MS and the BS currently connected to the MS, thereby improving total system efficiency of the BS. Further, the AMC scheme, the HARQ scheme and the FCS scheme can be used with other schemes for high-speed data transmission as well as the HSDPA scheme.

Currently, the 3G mobile communication system is being developed into a Fourth generation (4G) mobile communication system. Apart from previous mobile communication systems providing only wireless communication services, the 4G mobile communication system is being standardized with the goal of providing integrated wired and/or wireless communication services by efficiently combining a wireless communication network with a wire communication network. Accordingly, it is necessary to develop a technology capable of transmitting mass storage data with a wireless communication network having the capacity of a wired communication network.

In the 4G mobile communication system, an Orthogonal Frequency Division Multiplexing (OFDM) scheme is an available scheme for high-speed data transmission through a wired or wireless channel. The OFDM scheme, which transmits data using a multi-carrier, is a special type of a Multi-Carrier Modulation (MCM) scheme in which a serially input symbol sequence is converted into parallel symbol sequences and the parallel symbol sequences are modulated with a plurality of mutually orthogonal sub-carriers (or sub-carrier channels) before being transmitted.

A fundamental issue in the communication system described above lies in how efficiently and reliably data can be transmitted through a communication channel. The 4G (i.e., the next generation multimedia mobile communication system), requires a high-speed communication system capable of processing and transmitting various information such as images and wireless data. This is in contrast to earlier wireless communication systems which, for the most part, only provide a voice-based service. Accordingly, it is desirable to improve system efficiency using a channel coding scheme which is compatible with a communication system.

In wireless channel environments such as those of mobile communication systems, information may be lost due to unavoidable errors caused by various factors such as multi-path and other interference, shadowing, electric wave attenuation, time-varying noise and fading. The information loss may function as a factor deteriorating the entire performance of the mobile communication system because it may actually cause a serious distortion in transmitted signals.

Generally, in order to reduce the loss of information as described above, it is necessary to improve the transmission reliability of a system using various error control techniques based on the characteristics of individual channels. From among aforementioned error control techniques, an error correcting code is basically used to improve the transmission reliability.

The next generation communication system has been developed with the aim of providing mass storage data (e.g., a packet service communication system such as a fax) of various Quality of Services (QoSs) at a high-speed. When transmitting mass storage data at a high-speed, a loss of information is highly undesirable as it can cause system failures. Accordingly, an error correcting capability of the error correcting code (ECC) functions as an important factor for determining the entire QoS.

Representative codes of the ECC include a turbo code, a Low Density Parity Check (LDPC) code, etc.

The LDPC code is a code which can provide a superior performance gain in high-speed data transmission, as compared with a conventional convolutional codes which are primarily used for error correcting. Further, the LDPC code may effectively correct an error due to noise occurring in a wireless channel, thereby improving reliability of data transmission. Furthermore, the LDPC code may perform decoding by means of an iterative decoding algorithm, which is based on a sum-product algorithm, on a factor graph. A decoder of the LDPC code using these advantages has low complexity and may easily embody a parallel processing decoder, as compared with a decoder of the turbo code.

The turbo code has a superior performance level which is similar to a channel capacity limit in Shannon's channel coding theorem. The LDPC code shows performance having only a difference of about 0.04 dB for a Bit Error Rate (BER) of 10⁻⁵ by means of a block size of 10⁷ in the channel capacity limit in the Shannon's channel coding theorem. The Shannon's channel coding theorem shows that a reliable communication can be performed only for a data rate which does not exceed the capacity of a channel. For example, a random code having a very large block size has a performance which is similar to the channel capacity limit in the Shannon's channel coding theorem. However, when a Maximum a Posteriori (MAP) decoding or a Maximum Likelihood (ML) decoding is applied, a huge amount of load is laid on the calculation. Therefore, it is impossible to actually embody the random code. In the LDPC code, most elements have a value of 0 respectively and a very small number of elements, other than the elements having the value of 0, are defined by a parity check matrix having a value of 1. That is, the parity check matrix of the LDPC code has very small number of weights. Accordingly, the LDPC code can be decoded through iterative decoding also in a block code having a relatively long length. Further, when the block length of the block code is continuously increased, the LDPC code shows performance similar to the Shannon's channel capacity limit, similarly to the turbo code. Accordingly, the next generation communication system has actively used the LDPC code as the error correcting code. However, when coding is performed using a generation matrix similarly to a space-time code, the LDPC code cannot ensure superior performance. That is, the LDPC code has a low complexity when decoding is performed because its parity check matrix has small number of weights as described above. However, when the parity check matrix is converted to a generation matrix, the LDPC code has increased complexity in coding because a weight of the generation matrix increases.

Accordingly, for the next generation mobile communication system, coding techniques of new schemes have been researched. For example, a Concatenated Zigzag (CZZ) code has been proposed by Ping in 2001. The CZZ code has characteristics which are obtained by combining advantages of the turbo code and the LDPC code. The CZZ code has decoding and complexity which is lower than the turbo code because decoding is performed by the sum-product algorithm. Further, the CZZ code has an advantage in that, in a high code rate, an error floor occurs in a low BER as compared with the turbo code. Furthermore, the CZZ code has an advantage in that it has low coding complexity as compared with the LDPC code.

However, the CZZ code has a disadvantage in that its error correcting capability is inferior to that of the turbo code or the LDPC code. Accordingly, it is desirable to provide a system and a method for improving code rate performance and reducing coding complexity and decoding delay by enhancing the performance of the CZZ code.

### SUMMARY OF THE INVENTION

Accordingly, the present invention has been made to solve the above-mentioned problems occurring in the prior art, and it is an object of the present invention to provide an apparatus and a method for channel coding, which can improve system efficiency in the next generation mobile communication system.

It is another object of the present invention to provide an apparatus and a method which can improve code rate performance and reduce encoding complexity and decoding delay by enhancing the performance of a CZZ code.

It is further another object of the present invention to provide an Irregular CZZ (ICZZ) code capable of improving the performance of a CZZ code.

It is still another object of the present invention to provide an apparatus and a method which can reduce encoding complexity and decoding delay through an ICZZ code.

It is yet another object of the present invention to provide an algorithm for applying an ICZZ code.

In order to accomplish the aforementioned object, according to one aspect of the present invention, there is provided a method for channel coding in a mobile communication system, the method including the steps of dividing information bits of predetermined length into a predetermined number of sub-information bits according to a preset value; interleaving the divided sub-information bits, respectively; and coding the interleaved sub-information bits.

In order to accomplish the aforementioned object, according to another aspect of the present invention, there is provided a method for channel coding in a mobile communication system, the method including the steps of dividing information bits of length N into M sub-information bits according to a preset value; interleaving the M sub-information bits using corresponding interleavers; and coding the interleaved sub-information bits using at least one corresponding component encoder.

In order to accomplish the aforementioned object, according to further another aspect of the present invention, there is provided a method for channel decoding in a mobile communication system, the method including the steps of: adaptively receiving predetermined parallel parity bits; computing messages from check nodes to information nodes by a predetermined scheduling scheme, and outputting the computed messages; and receiving parallel input messages, computing the received messages through a sequential summing and obtaining a resulting sum, and outputting the resulting sum.

In order to accomplish the aforementioned object, according to still another aspect of the present invention, there is provided a coding apparatus for channel coding in a mobile communication system, the apparatus including a divider for dividing information bits of predetermined length into a predetermined number of sub-information bits according to a preset value; at least one interleaver for interleaving the divided sub-information bits; and a component encoder for coding the sub-information bits output from the interleaver.

In order to accomplish the aforementioned object, according to yet another aspect of the present invention, there is provided an apparatus for channel coding in a mobile communication system, the apparatus including a divider for dividing information bits of length N into M sub-information bits according to a preset value; at least one interleaver for performing a corresponding interleaving corresponding to the M sub-information bits; and a component encoder for performing coding corresponding to the sub-information bits interleaved through the interleaver.

In order to accomplish the aforementioned object, according to yet another aspect of the present invention, there is provided a decoding apparatus for channel decoding in a mobile communication system, the apparatus including an inner Single Input Single Output (SISO) block for adaptively receiving predetermined parallel parity bits, computing messages from check nodes to information nodes using a predetermined scheduling scheme, and outputting the computed messages; and an outer SISO block for receiving parallel input messages from the inner SISO block, computing the received messages using a sequential summing, and outputting a result sum obtained by the sequential summing.

### BRIEF DESCRIPTION OF THE DRAWINGS

The above and other objects, features and advantages of the present invention will be more apparent from the following detailed description taken in conjunction with the accompanying drawings, in which:

FIGS. 1a l and 1B are a diagram schematically illustrating a structure of an ICZZ encoder according to an embodiment of the present invention;

FIG. 2 is a diagram illustrating a zigzag code for describing functions according to an embodiment of the present invention;

FIGS. 3A and 3B are diagrams schematically illustrating structures of decoders for performing functions according to an embodiment of the present invention;

FIG. 4 is a diagram illustrating message flows based on use of a parallel encoder according to an embodiment of the present invention; and

FIG. 5 is a graph illustrating a comparison of BER performance of an Irregular Concatenated Zigzag (ICZZ) code according to an embodiment of the present invention.

### DETAILED DESCRIPTION OF THE PREFERRED EMBODIMENT

A preferred embodiment of the present invention will be described in detail herein below with reference to the accompanying drawings. In the following description, a detailed description of known functions and configurations incorporated herein will be omitted when it may obscure the subject matter of the present invention.

Before describing the present invention in detail, a definition for an Irregular Concatenated Zigzag (ICZZ) code proposed by the present invention will be described.

To realize the ICZZ code a various number of information bits input to each component encoder, i.e., each zigzag encoder.

For example, in the present embodiment, the number of overall information bits will be defined as “N”, the number of information bits input to a random i^{th} component encoder or a group of the information bits input to a random i^{th} component encoder will be defined as “gᵢ”, and the number of overall component encoders which are used will be defined as “N_{c}”. Herein, “gᵢ” may have various values according to values of i from 1 to N_{c}, and performance of the ICZZ code may change according to the values of “gᵢ”. In order to improve the performance of the ICZZ code according to an embodiment of the present invention, the ICZZ code is designed employing a density evolution technique. That is, the present invention obtains “gᵢ” and a parameter value “ρᵢ” of a CZZ code, which will be described later, by means of the density evolution technique.

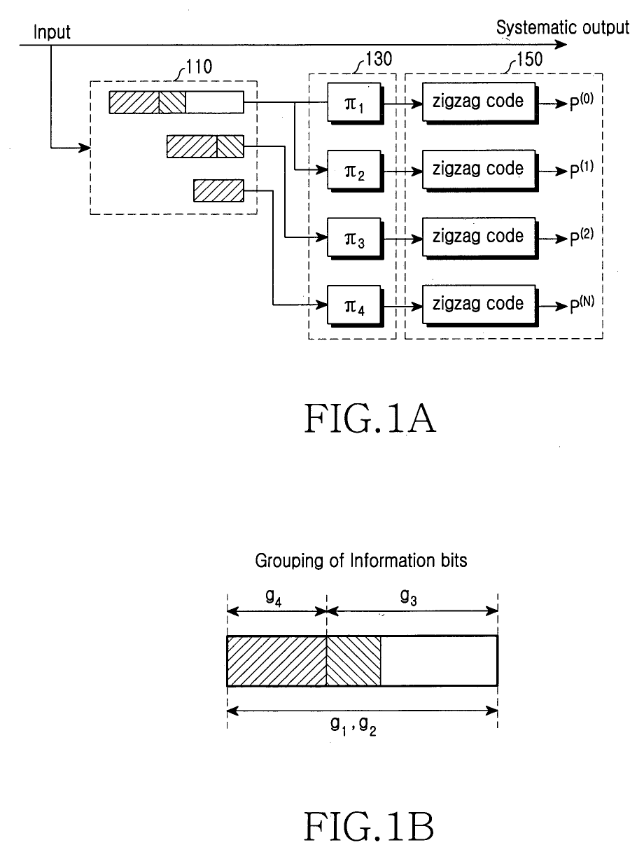

FIG. 1A is a diagram schematically illustrating a structure of an ICZZ encoder according to the embodiment of the present invention.

FIG. 1A shows an ICZZ encoder when the number N_{c} of overall component encoders is 4 (N=4). The ICZZ encoder includes a divider 110, an interleaver 130 and a component encoder 150. The interleaver 130 and the component encoder 150 may be constructed according to the number of input information bits. For example, the component encoder 150 may be a zigzag encoder. Hereinafter, an encoding process through the ICZZ encoder according to the embodiment of the present invention as described above will be described.

First, when an information bit of length N is input from an information bit input block of predetermined length, the divider 110 divides the input information bit according to a value of the predetermined number gᵢ of information bits, and outputs the divided information bits to the interleaver 130. Then, the interleaver 130 performs an interleaving for the divided information bits input from the divider 110, and outputs the interleaved information bits to the component encoder 150. The divided information bits are input to the interleaver 130 corresponding to the divided information bits. In other words, the divided information bits are into a corresponding part of the interleaver 130. That is, the interleaver 130 has a size corresponding to the number of the input information bits. The component encoder 150 inputs and codes information bits interleaved by the interleaver 130, and outputs the coded information bits. For example, the component encoder 150 may include at least one zigzag encoder using a zigzag code. The component encoder 150 has a size corresponding to the number of the input information bits (i.e., Nc or gᵢ). This may be summarized as follows.

(1) the information bit of the length N is input to the divider 110, and is divided into N_{c} sub-information bits according to the predetermined value gᵢ;

(2) the N_{c} sub-information bits are input to the corresponding interleaver 130. The N_{c} interleavers have a size equal to that of corresponding sub-information bits as described above; and

(3) the sub-information bits interleaved by the interleaver 130 are input to the corresponding component encoder 150.

Hereinafter, the zigzag code applied to the embodiment of the present invention will be described with reference to the accompanying drawing.

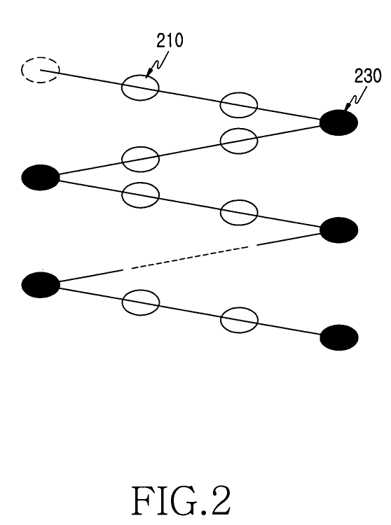

FIG. 2 is a diagram illustrating the zigzag code for describing functions according to the embodiment of the present invention. A zigzag code having a value of 2 (ρ=2) as a parameter value p for the zigzag code. Each white circle 210 represents an information bit and each black circle 230 represents a parity bit. Herein, the fact that the parameter has the value of 2 denotes that one parity bit is generated every two information bits.

In the ICZZ code according to the embodiment of the present invention, ρⱼ represents the parameter value ρ of the zigzag code used in an j^{th} component encoder. For example, when the first component encoder of FIG. 1A uses the zigzag code of FIG. 2, ρᵢ is 2.

Hereinafter, the embodiment of the present invention will be described in detail with reference to FIGS. 1A, 1B and 2.

As described in FIGS. 1A and 1B, the encoder of the ICZZ code according to the embodiment of the present invention includes the divider 110 being shown as multiple blocks, the interleaver 130 and the component encoder 150 having different zigzag codes connected in parallel to each other. The blocks denote blocks of information bits including a group gᵢ (1≦i≦Nc) of the information bits input to a predetermined i^{th} component encoder.

From FIGS. 1A and 1B, one can see that the group of the information bits or the number of information bits may be different as i increases, and includes groups having predetermined restricted sizes, e.g., g₁, g₂, g₃ and g₄ as shown in FIGS 1A and 1B.

In the meantime, the ratio of information bits in an i^{th} group among all information bits is defined as λᵢ (gᵢ/N). The another parameter ρⱼ is defined, which denotes a (ρⱼ, 0)-zigzag code used in an j^{th} component encoder. Herein, ρᵢ and ρⱼ are crucial parameters to determine the performance of the ICZZ codes according to the embodiment of the present invention, and are computed using the density evolution technique as the following description.

The encoding process of the j^{th} component encoder may be represented by Equation 1 below.

$$\begin{matrix}{P}_{1} = {\sum }_{k = 1}^{{ρ}_{j}} {I}_{k} mod 2 \\ {P}_{i} = {\sum }_{k = 1}^{{ρ}_{j}} {I}_{{ρ}_{j} ( i - 1 ) + K} + {P}_{i - 1} mod 2 , i = 2 , 3 , … , \frac{N}{{ρ}_{j}}\end{matrix} \qquad Equation 1$$

In Equation 1, Iₖ denotes k^{th} information, Pᵢ denotes an i^{th} parity bit, and N denotes the number of overall information bits.

It is possible to obtain the code rate of the ICZZ code according to the embodiment of the present invention by using Equation 1. That is, when λᵢ is gᵢ/N, the code rate of the ICZZ code according to the embodiment of the present invention may be represented by Equation 2 below.

$$Coderate = 1 / ( 1 + {\sum }_{j = 1}^{{N}_{c}} \frac{{λ}_{j}}{{ρ}_{j}} ) \qquad Equation 2$$

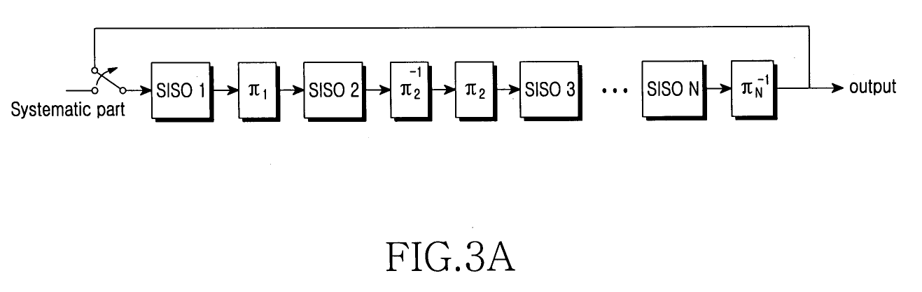

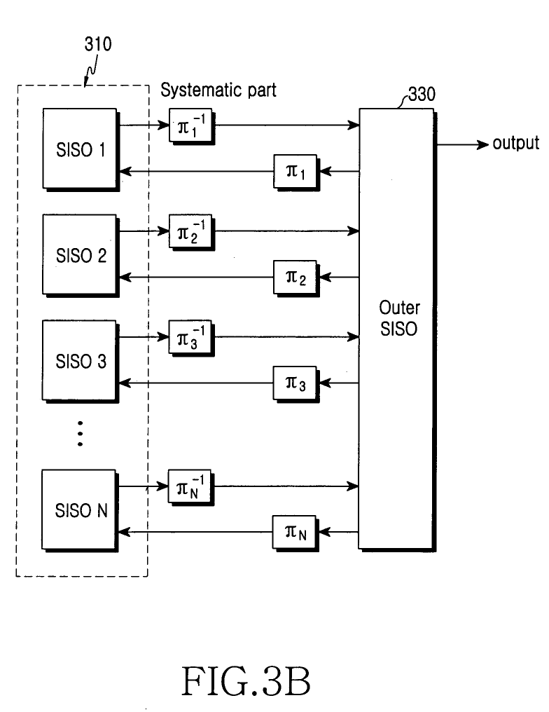

FIGS. 3A and 3B are diagrams schematically illustrating structures of decoders for performing functions according to the embodiment of the present invention. FIG. 3A shows a general serial decoder and FIG. 3B shows a parallel decoder according to the embodiment of the present invention.

Before describing FIGS. 3A and 3B, a generally known decoding algorithm of the ICZZ code performs decoding of two levels, i.e., performs decoding in response to messages passed in each component encoder and messages passed between component encoders. The two-way scheduling and the sum-product algorithm are used in each component encoder, and the turbo coding principle is used between the component encoders.

First, the ICZZ code uses four component codes having the best performance for code rates ½, ⅓, ¼ and ⅕. the four component codes having the best performance code rates are determined using analytical methods and simulations. However, for the ICZZ code, more component codes may be necessary to achieve sufficient performance compared to the CZZ code. Therefore, using the serial decoder shown in FIG. 3A may cause decoding delays and disturb the fast decoding.

Accordingly, the embodiment of the present invention proposes the parallel decoder as shown in FIG. 3B. It is more efficient to be used for the ICZZ code in the sense of decoding delay because the gain for decoding delay is larger as the number of component codes increases.

In FIG. 3B, a reference number 310 denotes an inner Single Input Single Output (SISO), which is constructed using small SISO blocks corresponding to zigzag decoders. A reference number 330 denotes an outer SISO.

In more detail, predetermined information and parity bits are adaptively input to the corresponding small SISO blocks. Each small SISO block in the inner SISO block 310 computes messages from check nodes to information nodes by the two-way scheduling as described above, and outputs the computed messages.

In the outer SISO block 330, the output messages from the information node to the each small SISO block are calculated by the sum of messages from edges other than one carrying an output message. The update speed on the messages is slower compared with the serial encoder as shown in FIG. 3A. Accordingly, a greater number of iterations are necessary in order to obtain the same performance as that which is achieved when using the serial encoder. However, the overall decoding delay is smaller because decoding can be performed in a parallel process for each small SISO block.

Table 1 below shows a comparison of the serial encoder and the parallel encoder according to decoding delay.

TABLE 1

| Decoder structure | Decoding delay |
|---|---|
| Serial encoder | 2(Nc)D(II) + (Nc)D(IS) |
| Parallel encoder | 2D(II) + D(IS) + D(OS) |

In Table 1, D(IS), D(OS) and D(Π) represent delays caused by the inner SISO blocks, the outer SISO 330 block and the interleaver/deinterleaver (where the interleaver/deinterleaver is illustrated as Interleaver: Π₁, Π₂, Π₃, Π_{N}; and Deinterleaver: Π₁⁻¹, Π₂⁻¹, Π₃⁻¹, Π_{N}⁻¹) as shown in FIG. 3B. D(OS) caused by the outer SISO block may be neglected compared to other delays.

One can see that the decoding delay does not depend on the number N_{c} of overall component encoders in the case of the parallel encoder of FIG. 3B from Table 1. Therefore, the decoding delay decreases as N_{c} increases compared to the serial encoder of FIG. 3A. Therefore, the parallel encoder is very important in order to reduce the decoding delay which occurs when the ICZZ codes are used.

Hereinafter, a message transfer process between the inner SISO blocks and the outer SISO block when using the parallel encoder according to the embodiment of the present invention illustrates above will be described.

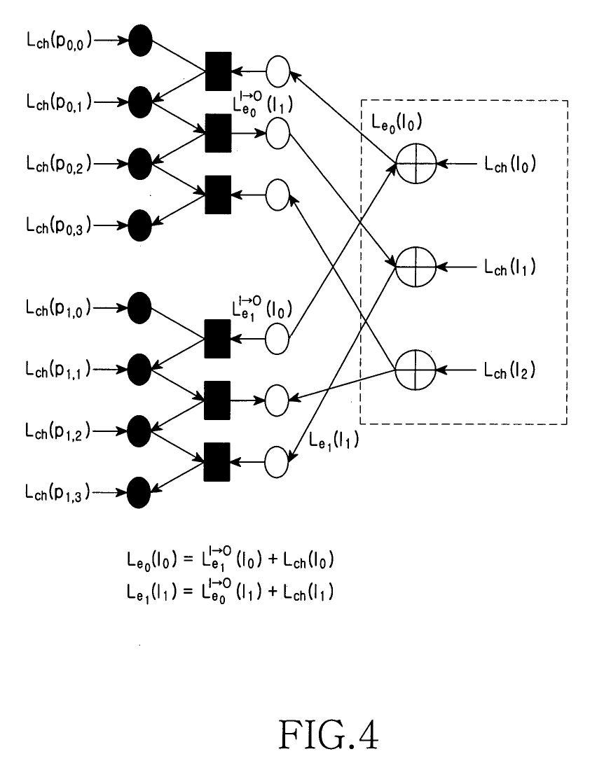

FIG. 4 is a diagram illustrating message flows based on use of a parallel encoder according to the embodiment of the present invention.

Referring to FIG. 4, L_{ch}(m) denotes a Log Likelihood Ratio (LLR) of m, corresponding to log(P(m=1|\overline{m})/p(m=−1|\overline{m})), where \overline{m} is a received value from a channel, m is a transmitted value, and p is a probability. Lₑ_{ᵢ}^{I→O}(Iⱼ)(1≦i≦N_{c}, 0≦j≦N−1) denotes extrinsic information from a predetermined i^{th} small SISO block of the inner SISO block 310 to a predetermined j^{th} information node in the outer SISO block 330 of FIG. 3B and is calculated using a method such as the decoding algorithm of the zigzag code. Lₑ_{ᵢ}(Iⱼ)(0≦j≦N−1) denotes the extrinsic information from the i^{th} small SISO block of the inner SISO block 310 to the j^{th} information node in the outer SISO block 330 and is calculated as represented by Equation 3 below.

$${L}_{{e}_{i}} ( {I}_{j} ) = {L}_{ch} ( {I}_{j} ) + {{\sum }_{k = 1}^{{N}_{c}}}_{k \neq 1} {L}_{{e}_{k}}^{l -> O} ( {I}_{j} ) , 1 \leq j \leq N , 1 \leq i \leq {N}_{c} \qquad Equation 3$$

In Equation 3, Lₑ_{ᵢ}^{I→O}(Iⱼ) and Lₑ_{ᵢ}(Iⱼ) may be zero according to i if an j^{th} information bit is not input to an i^{th} component code. The decoding is processed by exchanging Lₑ_{ᵢ}^{I→O}(Iⱼ) and Lₑ_{ᵢ}(Iⱼ) between the inner SISO block 310 and the outer SISO block 330 by a fixed number of times.

Hereinafter, an analysis of the ICZZ code based on the density evolution as described above will be described.

The density evolution has been proposed by Richardson, Urbanke, Chung., etc., for use. Because the history for the density evolution departs from the scope of the present invention, the detailed description will be omitted here.

When a function used for more efficient analysis in the density evolution for CZZ codes is defined as φ(●), φ(●) may be represented by Equation 4 below.

$$ϕ ( x ) = 1 - \frac{1}{\sqrt{4 π x}} {\int }_{R} tanh \frac{u}{2} {ⅇ}^{- \frac{{( u - x )}^{2}}{4 x}} ⅆ u , x > 0 \qquad Equation 4$$

where φ(0)=1, φ(∞)=0.

When a threshold obtained by the density evolution is called a channel parameter σ*, the threshold σ* may be determined by conditions as represented by Equation 5 below.

$$\begin{matrix}if σ < {σ}^{*} , {lim}_{l -> ∞} {P}_{e}^{( l )} = 0 \\ if σ > {σ}^{*} , {lim}_{l -> ∞} {P}_{e}^{( l )} > 0\end{matrix} , and \qquad Equation 5$$

In Equation 5, σ is a standard deviation of Additive White Gaussian Noise (AWGN) and Pₑ^{(l)} is an error probability of information bits after an l^{th} iteration. Note that the transmitted signal power is normalized to one.

The present invention applies the density evolution in order to obtain recursion equations for ICZZ codes with the two-way scheduling. It is possible to compute optimal parameters λᵢ and ρⱼ by means of the density evolution. We define the ratio of information nodes with a degree k by a Gaussian function f(k) (1≦k≦Nc) applied to the density evolution.

The density evolution is calculated by two levels, corresponding to a message passed from the outer SISO block 330 to the inner SISO block 310, and a message passed in each small SISO block.

First, we consider the message passed from the outer SISO block 330 to the inner SISO block 310.

Means of messages from the i^{th} inner SISO block to the j^{th} information node in the outer SISO block 330 and vice versa will be referred to as m_{L}_{ₑᵢ}_{^{I→O}}_{(I}_{ⱼ}₎ and m_{L}_{ₑᵢ}_{(I}_{ⱼ}₎, respectively. m_{L}_{ₑᵢ}_{(I}_{ⱼ}₎ may be calculated by Equation 6 below.

$${m}_{{L}_{{e}_{i}} ( {l}_{j} )} = {{\sum }_{k = 1}^{{N}_{c}}}_{k \neq 1} {m}_{{L}_{{e}_{ki}}^{l -> O} ( {I}_{j} )} . \qquad Equation 6$$

In Equation 6, if the j^{th} information node is not included in the group gᵢ of the information bits as described above, both m_{L}_{ₑᵢ}_{^{I→O}}_{(I}_{ⱼ}₎ and m_{L}_{ₑᵢ}_{(I}_{ⱼ}₎ are not considered. m_{L}_{ₑᵢ}_{(I}_{ⱼ}₎ has different values according to j because the information nodes may have different degrees for j.

When m_{L}_{ₑᵢ}_{(I}_{ⱼ}₎=m_{L}_{ₑᵢ}_{(I}_{ₖ}₎, Iⱼ and Iₖ have the same degree. Therefore, m_{L}_{ₑᵢ}_{(I}_{ⱼ}₎ for all j is partitioned into several groups according to degree of information nodes for all j. m_{L}_{ₑᵢ}_{(I}_{^{t}}₎ denotes a mean value of information nodes with degree t.

Let Lₑ_{ᵢ}(I) be a message from randomly selected information node in the outer SISO block 330 to an i^{th} small SISO block. Then Iₑ_{ᵢ}(I) has the following Gaussian mixture density fₘ_{_{Lei(I)}}(.) as represented by Equation 7 below.

$${f}_{{m}_{{L}_{{e}_{i}} ( l )}} ( x ) = \frac{( {\sum }_{t = i}^{{N}_{c}} {tf}_{t} \cdot {f}_{{m}_{{L}_{{e}_{i}} ( {l}^{t} )}} ( x ) )}{( {\sum }_{t = i}^{{N}_{c}} {tf}_{t} )} \qquad Equation 7$$

Next, we consider messages passed in a c^{th} small SISO block. Received values for g_{c} information and g_{c}/ρ_{c} parity bits are input to the c^{th} small SISO block. I_{c}(k) (0≦k≦gᵢ−1) denotes an k^{th} information node included in the c^{th} small SISO block, which is constructed by the interleaving of information bits included in gᵢ.

The decoding using the two-way scheduling is initialized by inputting Lₑ_{ₖ}(I) into all information nodes. In the present invention, it is possible to obtain means of messages from an j^{th} check node to a left-parity node and a right-parity node in an l^{th} iteration by mₚ_{ₗ}_{^{(I)}}₍ⱼ₎ and mₚ_{ᵣ}_{^{(I)}}₍ⱼ₎, respectively. The two-way scheduling used in each component decoder is divided into three levels. That is, recursion equations using three density evolution are calculated according to three levels as represented by Equations 8, 9 and 10 below.

$$\begin{matrix}{m}_{{p}_{l}^{( l )} ( j )} = {ϕ}^{- 1} ( {[ 1 - \frac{( {\sum }_{t = i}^{{N}_{c}} {tf}_{t} ϕ ( {m}_{{u}_{0}} + {m}_{{L}_{{e}_{i}} ( {l}^{t} )} ) )}{{\sum }_{t = i}^{{N}_{c}} {tf}_{t}} ]}^{{ρ}_{c}} \cdot [ 1 - ϕ ( {m}_{{u}_{0}} + {m}_{{p}_{l}^{( l )} ( j - 1 )} ) ] ) , j = 1 , … , \frac{{g}_{c}}{{ρ}_{c}} , & Equation 8 \\ {m}_{{p}_{r}^{( l )} ( j )} = {ϕ}^{- 1} ( {[ 1 - \frac{( {\sum }_{t = i}^{{N}_{c}} {tf}_{t} ϕ ( {m}_{{u}_{0}} + {m}_{{L}_{{e}_{i}} ( {l}^{t} )} ) )}{{\sum }_{t = i}^{{N}_{c}} {tf}_{t}} ]}^{{ρ}_{c}} \cdot [ 1 - ϕ ( {m}_{{u}_{0}} + {m}_{{p}_{r}^{( l )} ( j + 1 )} ) ] ) , j = 1 , … , \frac{{g}_{c}}{{ρ}_{c}} , & Equation 9 \\ {m}_{{L}_{{e}_{i}}^{l -> O} ( {l}_{j} )} = {ϕ}^{- 1} ( {[ 1 - \frac{( {\sum }_{t = i}^{{N}_{c}} {tf}_{t} ϕ ( {m}_{{u}_{0}} + {m}_{{L}_{{e}_{i}} ( {l}^{t} )} ) )}{{\sum }_{t = i}^{{N}_{c}} {tf}_{t}} ]}^{{ρ}_{c} - 1} \cdot \\ [ 1 - ϕ ( {m}_{{u}_{0}} + {m}_{{p}_{l}^{( l )} ( j - 1 )} ) ] \cdot [ 1 - ϕ ( {m}_{{u}_{0}} + {m}_{{p}_{r}^{( l )} ( j )} ) ] ) , j = 1 , … , {g}_{c} . & Equation 10\end{matrix}$$

In Equation 10, m_{L}_{ₑᵢ}_{^{I→O}}_{(I}_{ⱼ}₎ is nearly the same regardless of j. Therefore, it is not necessary to consider j, which may be omitted in Equation 10. Hereinafter, m_{L}_{ₑᵢ}_{^{I→O}}_{(I)} is used instead of m_{L}_{ₑᵢ}_{^{I→O}}_{(I}_{ⱼ}₎ according to omission of j.

The goal of the present invention is to obtain the mean of the messages at the information node during the iterations, which may be recursively computed by using equations 7 to 10. The process for obtaining the mean of the messages at the information node are divided into five levels as follows:

First, the iteration is initialized by an initial value

$${m}_{{u}_{0}} \frac{2}{{σ}^{2}}$$

from the channel, where σ² is noise variance and mean values of other messages in Equations 8 to 10 are zero;

Second, m_{L}_{ₑᵢ}_{^{I→O}}_{(I)} (1≦i≦N_{c}) is separately derived using Equations 8 to 10 in the small SISO blocks;

Third, m_{L}_{ₑᵢ}_{(I}_{ⱼ}₎ for all j is obtained using Equation 7 and is partitioned. m_{L}_{ₑᵢ}_{(I}_{^{t}}₎ for all t is derived;

Fourth, the second process and the third process are repeated a fixed number of times; and

Fifth, it is determined if

$${\sum }_{k = 1}^{{N}_{c}} {m}_{{L}_{{e}_{ki}}^{l -> O} ( {I}_{j} )}$$

converges to infinity.

The threshold σ* as described above is obtained by repeating the five levels. The values of σ* for ICZZ codes are calculated according to parameters as shown in Table 2.

TABLE 2
Parameters

| | |
|---|---|
| λᵢ | ρᵢ |

| | | |
|---|---|---|
| λᵢ | 1 | 1, 1 ≦ i ≦ 7 |
| λ₂ | 1 | |
| λ₃ | 1 | |
| λ₄ | 0.722 | |
| λ₅ | 0.426 | |
| λ₆ | 0.426 | |
| λ₇ | 0.426 | |

Table 2 shows parameters of an ICZZ code with a code rate ⅙ and a threshold σ* of 1.83. The ICZZ code with the parameters shown in Table 2 has an asymptotic performance which is about 0.62 dB better than conventional CZZ codes.

Table 3 is an exemplary case, which shows parameters of an ICZZ code with a code rate ½ and a threshold σ* of 0.937.

TABLE 3
Parameters

| | |
|---|---|
| λᵢ | ρᵢ |

| | | |
|---|---|---|
| λᵢ | 1 | 5, 1 ≦ i ≦ 7 |
| λ₂ | 1 | |
| λ₃ | 1 | |
| λ₄ | 0.722 | |
| λ₅ | 0.426 | |
| λ₆ | 0.426 | |
| λ₇ | 0.426 | |

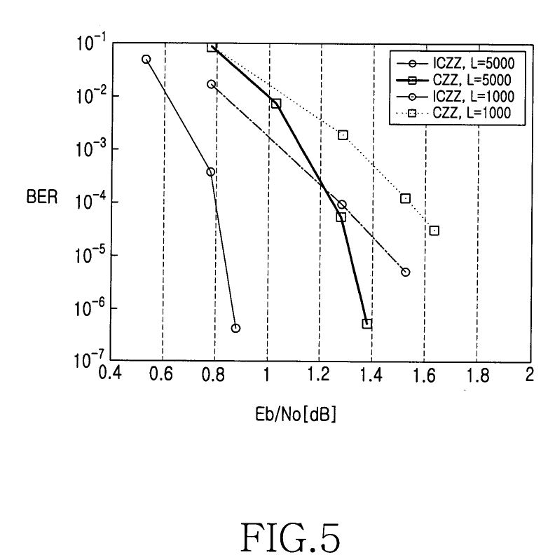

FIG. 5 is a graph illustrating a comparison of BER performance of an ICZZ code according to the embodiment of the present invention, and shows a comparison of BER performance between a CZZ code with the code rate ⅙ as illustrated in Table 2 and an ICZZ code.

For the simulations in FIG. 5, it is assumed that 1000 and 5000 information bits are used, respectively. As conditions for the simulations in FIG. 5, a BPSK modulation, a Max Log-MAP algorithm, random interleavers, 30 iterations, and an AWGN channel are assumed. Further, the ICZZ code shown in Table 2 and the CZZ code with five component codes are used.

As described above, the present invention proposes an ICZZ code capable of improving performance of a CZZ code proposed by Ping, thereby enhancing error correcting capability and reducing encoding complexity and decoding delay while maintaining the advantages of the CZZ code.

According to an apparatus and a method for channel encoding/decoding using a CZZ code in a mobile communication system of the present invention, it is possible to improve system efficiency by means of a channel encoding technique used in the next generation mobile communication system.

Further, according to the present invention, encoding complexity and decoding delay can be reduced and system efficiency can be enhanced by improving performance of a CZZ code in a mobile communication system.

While the present invention has been shown and described with reference to certain preferred embodiments thereof, it will be understood by those skilled in the art that various changes in form and details may be made therein without departing from the spirit and scope of the present invention as defined by the appended claims.

What is claimed is:

1. A method for channel coding in a mobile communication system, the method comprising the steps of:
dividing information bits of predetermined length into a predetermined number of sub-information bits according to a preset value;
interleaving the divided sub-information bits respectively; and coding the interleaved sub-information bits.

2. The method as claimed in claim 1, wherein the preset value includes a preset number of information bits.

3. The method as claimed in claim 2, wherein the preset number of the information bits is determined by means of a density evolution technique.

4. The method as claimed in claim 1, wherein the step of coding the interleaved sub-information bits is performed by at least one component encoder corresponding to a number of input information bits.

5. The method as claimed in claim 1, wherein the step of interleaving the divided sub-information bits is performed by at least one interleaver.

6. The method as claimed in claim 1, wherein the step of coding the interleaved and output sub-information bits is performed by means of a zigzag code.

7. The method as claimed in claim 1, wherein the interleaved sub-information bits include irregular concatenated zigzag codes.

8. A method for channel coding in a mobile communication system, the method comprising the steps of:
dividing information bits of length N into M sub-information bits according to a preset value;
interleaving the M sub-information bits using corresponding interleavers ; and
coding the interleaved sub-information bits using at least one corresponding component encoder.

9. The method as claimed in claim 8, wherein the length N includes a number of overall input information bits.

10. The method as claimed in claim 8, wherein the preset value is set according to a number of the information bits input to the component encoder.

11. The method as claimed in claim 8, wherein the preset value is obtained by means of a density evolution technique.

12. The method as claimed in claim 8, wherein M is determined according to a number of component encoders.

13. The method as claimed in claim 8, wherein the interleaver has a size corresponding to a size of the sub-information bits.

14. The method as claimed in claim 8, wherein the step of coding the interleaved sub-information bits is performed using at least one zigzag encoder using a zigzag code.

15. The method as claimed in claim 8, wherein the interleaved sub-information bits include irregular concatenated zigzag codes.

16. The method as claimed in claim 15, wherein the irregular concatenated zigzag code has a code rate defined by
$$Coderate = 1 / ( 1 + {\sum }_{j = 1}^{{N}_{c}} \frac{{λ}_{j}}{{ρ}_{j}} ) ,$$
wherein λᵢ denotes a code rate of information bits belonging to an j^{th} group among overall information bits, ρⱼ denotes a parameter of a zigzag code used in an j^{th} component encoder, and Nc denotes a number component encoders which are used.

17. The method as claimed in claim 8, wherein the step of coding the interleaved sub-information bits by the component encoder is defined by
$$\begin{matrix}{P}_{1} = {\sum }_{k = 1}^{{ρ}_{j}} {I}_{k} mod 2 \\ {P}_{i} = {\sum }_{k = 1}^{{ρ}_{j}} {I}_{{ρ}_{j} ( i - 1 ) + K} + {P}_{i - 1} mod 2 , i = 2 , 3 , … , \frac{N}{{ρ}_{j}} ,\end{matrix} ; and$$
wherein Iₖ denotes k^{th} information, Pᵢ denotes an i^{th} parity bit, ρⱼ denotes a parameter of a zigzag code used in an j^{th} component encoder, and N denotes the number of overall information bits.

18. A method for channel decoding in a mobile communication system, the method comprising the steps of:
adaptively receiving predetermined parallel parity bits; computing messages from check nodes to information nodes by a predetermined scheduling scheme, and outputting the computed messages; and
receiving parallel input messages, computing the received messages through a sequential summing and obtaining a resulting sum, and outputting the resulting sum.

19. The method as claimed in claim 18, wherein the predetermined scheduling scheme uses a density evolution technique to obtain recursion equations for an irregular concatenated zigzag code.

20. The method as claimed in claim 18, wherein the channel decoding is iteratively performed a predetermined number of times, the predetermined number of times corresponding to a system setting.

21. A coding apparatus for channel coding in a mobile communication system, the apparatus comprising:
a divider for dividing information bits of predetermined length into a predetermined number of sub-information bits according to a preset value;
at least one interleaver for interleaving the divided sub-information bits; and
a component encoder for coding the sub-information bits output from the interleaver.

22. The apparatus as claimed in claim 21, wherein the preset value includes a preset number of information bits.

23. The apparatus as claimed in claim 22, wherein the preset number of information bits is determined using a density evolution technique.

24. The apparatus as claimed in claim 21, wherein the component encoder includes at least one zigzag encoder corresponding to a number of information bits which are input.

25. The apparatus as claimed in claim 21, wherein the interleaved sub-information bits which are output from the interleaver include irregular concatenated zigzag codes.

26. An apparatus for channel coding in a mobile communication system, the apparatus comprising:
a divider for dividing information bits of length N into M sub-information bits according to a preset value;
at least one interleaver for performing a corresponding interleaving corresponding to the M sub-information bits; and
a component encoder for performing coding corresponding to the sub-information bits interleaved through the interleaver.

27. The apparatus as claimed in claim 26, wherein the length N includes a number of overall input information bits.

28. The apparatus as claimed in claim 26, wherein the preset value is set according to a number of the information bits input to the component encoder.

29. The apparatus as claimed in claim 26, wherein the preset value is obtained using a density evolution technique.

30. The apparatus as claimed in claim 26, wherein the M is determined according to a number of component encoders.

31. The apparatus as claimed in claim 26, wherein the interleaver has a size corresponding to a size of the sub-information bits.

32. The apparatus as claimed in claim 26, wherein the component encoder includes at least one zigzag encoder using a zigzag code.

33. The apparatus as claimed in claim 26, wherein the interleaved sub-information bits are output from the interleaver and include irregular concatenated zigzag codes.

34. The apparatus as claimed in claim 33, wherein the irregular concatenated zigzag code has a code rate defined by
$$Coderate = 1 / ( 1 + {\sum }_{j = 1}^{{N}_{c}} \frac{{λ}_{j}}{{ρ}_{j}} ) ,$$
wherein λᵢ denotes a code rate of information bits belonging to an j^{th} group among overall information bits, ρⱼ denotes a parameter of a zigzag code used in an j^{th} component encoder, and N_{c} denotes a number of overall used component encoders.

35. The apparatus as claimed in claim 26, wherein coding by the component encoder is defined by
$$\begin{matrix}{P}_{1} = {\sum }_{k = 1}^{{ρ}_{j}} {I}_{k} mod 2 , \\ {P}_{i} = {\sum }_{k = 1}^{{ρ}_{j}} {I}_{{ρ}_{j} ( i - 1 ) + K} + {P}_{i - 1} mod 2 , i = 2 , 3 , … , \frac{N}{{ρ}_{j}} ,\end{matrix} ; and$$
wherein Iₖ denotes k^{th} information, Pᵢ denotes an i^{th} parity bit, ρⱼ denotes a parameter of a zigzag code used in an j^{th} component encoder, and N denotes a number of overall information bits.

36. A decoding apparatus for channel decoding in a mobile communication system, the apparatus comprising:
an inner Single Input Single Output (SISO) block for adaptively receiving predetermined parallel parity bits, computing messages from check nodes to information nodes using a predetermined scheduling scheme, and outputting the computed messages; and
an outer SISO block for receiving parallel input messages from the inner SISO block, computing the received messages using a sequential summing, and outputting a result sum obtained by the sequential summing.

37. The apparatus as claimed in claim 36, wherein the inner SISO block includes a plurality of SISO blocks connected in parallel.
